(19) United States
(12) Patent Application Publication
(10) Pub. No.: US 2024/0055746 A1
(43) Pub. Date: Feb. 15, 2024

(54) METHOD, APPARATUS, AND COMPUTER-READABLE STORAGE MEDIUM FOR ADJUSTING RESONANT CAVITY

(71) Applicant: Alibaba Damo (Hangzhou) Technology Co., Ltd., Hangzhou (CN)

(72) Inventors: Tian XIA, Hangzhou (CN); Jianjun CHEN, Hangzhou (CN); Feng WU, Hangzhou (CN); Ran GAO, Hangzhou (CN); Hao DENG, Hangzhou (CN); Huihai ZHAO, Beijing (CN)

(21) Appl. No.: 18/357,501

(22) Filed: Jul. 24, 2023

(30) Foreign Application Priority Data
Aug. 10, 2022 (CN) 202210956778.4

(51) Int. Cl. H01P 3/12; G06F 30/20

(52) U.S. Cl. CPC H01P 3/12; G06F 30/20

(57) ABSTRACT

A method for adjusting a resonant cavity includes: acquiring a construction parameter of a coplanar waveguide; determining, based on the construction parameter, an equivalent inductance of the coplanar waveguide, in which the equivalent inductance is a superposition of geometric inductance and kinetic inductance, and the equivalent inductance represents current density distribution on a metal surface of the coplanar waveguide; determining, based on the equivalent inductance, a resonance frequency of the resonant cavity formed by the coplanar waveguide, in which the resonance frequency is an analytical function with the construction parameter of the coplanar waveguide as a variable; and adjusting the resonance frequency of the resonant cavity to a target resonance frequency by adjusting a value of the construction parameter of the coplanar waveguide.

### CROSS-REFERENCE TO RELATED APPLICATIONS

The present application claims priority to and the benefits of Chinese Patent Application No. 202210956778.4, filed on Aug. 10, 2022, which is incorporated herein by reference in its entirety.

### TECHNICAL FIELD

The present disclosure relates to the field of superconducting quantum, and in particular to a method, apparatus, and a computer-readable storage medium for adjusting a resonant cavity.

### BACKGROUND

In the related art, when adjustments are made to a superconducting quantum device, it is time and energy consuming to analyze a resonant cavity of the superconducting quantum device using a method for analyzing common metal, and in the related art, when the parameter estimation is performed on a coplanar waveguide of the superconducting quantum device by employing a formula, the computation result is not sufficiently accurate because the computation method is not sufficiently reasonable.

Therefore, in the related art, there are technical problems of low adjustment efficiency and inaccurate results for the resonant cavity in the superconducting quantum device.

For the above-mentioned problems, no effective solution has been proposed yet.

### SUMMARY

Embodiments of the present disclosure provide a method for adjusting a resonant cavity. The method includes: acquiring a construction parameter of a coplanar waveguide; determining, based on the construction parameter, an equivalent inductance of the coplanar waveguide, in which the equivalent inductance is a superposition of geometric inductance and kinetic inductance, and the equivalent inductance represents current density distribution on a metal surface of the coplanar waveguide; determining, based on the equivalent inductance, a resonance frequency of the resonant cavity formed by the coplanar waveguide, in which the resonance frequency is an analytical function with the construction parameter of the coplanar waveguide as a variable; and adjusting the resonance frequency of the resonant cavity to a target resonance frequency by adjusting a value of the construction parameter of the coplanar waveguide.

Embodiments of the present disclosure provide a method for adjusting a resonant cavity. The method includes: displaying a parameter input control on an interactive interface; receiving a construction parameter of a coplanar waveguide in response to an operation to the parameter input control; receiving a frequency determination instruction; determining, based on the construction parameter, an equivalent inductance of the coplanar waveguide in response to the frequency determination instruction, and determining, based on the equivalent inductance, a resonance frequency of the resonant cavity formed by the coplanar waveguide, wherein the equivalent inductance is a superposition of geometric inductance and kinetic inductance, and the equivalent inductance represents current density distribution on a metal surface of the coplanar waveguide, and the resonance frequency is an analytical function with the construction parameter of the coplanar waveguide as a variable; receiving a parameter adjustment instruction; and adjusting the resonance frequency of the resonant cavity to a target resonance frequency in response to the parameter adjustment instruction by adjusting a value of the construction parameter of the coplanar waveguide.

Embodiments of the present disclosure provide an apparatus for adjusting a resonant cavity. The apparatus includes: an acquisition module, configured to acquire a construction parameter of a coplanar waveguide; a first determination module, configured to determine, based on the construction parameter, an equivalent inductance of the coplanar waveguide, wherein the equivalent inductance is a superposition of geometric inductance and kinetic inductance, and the equivalent inductance represents current density distribution on a metal surface of the coplanar waveguide; a second determination module, configured to determine, based on the equivalent inductance, a resonance frequency of the resonant cavity formed by the coplanar waveguide, wherein the resonance frequency is an analytical function with the construction parameter of the coplanar waveguide as a variable; and an adjustment module, configured to adjust the resonance frequency of the resonant cavity to a target resonance frequency by adjusting a value of the construction parameter of the coplanar waveguide.

Embodiments of the present disclosure provide a non-transitory computer-readable storage medium. The non-transitory computer-readable storage medium stores a program that is executable by a device to cause the device to perform operations including: acquiring a construction parameter of a coplanar waveguide; determining, based on the construction parameter, an equivalent inductance of the coplanar waveguide, wherein the equivalent inductance is a superposition of geometric inductance and kinetic inductance, and the equivalent inductance represents current density distribution on a metal surface of the coplanar waveguide; determining, based on the equivalent inductance, a resonance frequency of a resonant cavity formed by the coplanar waveguide, wherein the resonance frequency is an analytical function with the construction parameter of the coplanar waveguide as a variable; and adjusting the resonance frequency of the resonant cavity to a target resonance frequency by adjusting a value of the construction parameter of the coplanar waveguide.

Embodiments of the present disclosure provide a computer device. The computer device includes: a memory configured to store a computer program, and one or more processors configured to run the computer program stored in the memory, to cause the computer device to execute operations comprising: acquiring a construction parameter of a coplanar waveguide; determining, based on the construction parameter, an equivalent inductance of the coplanar waveguide, wherein the equivalent inductance is a superposition of geometric inductance and kinetic inductance, and the equivalent inductance represents current density distribution on a metal surface of the coplanar waveguide; determining, based on the equivalent inductance, a resonance frequency of a resonant cavity formed by the coplanar waveguide, wherein the resonance frequency is an analytical function with the construction parameter of the coplanar waveguide as a variable; and adjusting the resonance frequency of the resonant cavity to a target resonance frequency by adjusting a value of the construction parameter of the coplanar waveguide.

### BRIEF DESCRIPTION OF THE DRAWINGS

The accompanying drawings described herein are intended to provide further understanding of the present disclosure and constitute a part of this disclosure. Exemplary embodiments of the present disclosure and the description thereof are used for explaining the present disclosure rather than constituting improper limitations to the present disclosure. In the accompanying drawings:

FIG. 1 shows a structural block diagram of hardware of an example computer terminal for implementing a method for adjusting a resonant cavity;

FIG. 2 is a flowchart of an example method for adjusting a resonant cavity according to some embodiments of the present disclosure;

FIG. 3 is a flowchart of an example method for adjusting a resonant cavity according to some embodiments of the present disclosure;

FIG. 4 is a comparison schematic diagram of an example computation result and an example simulation result of kinetic inductance according to some embodiments of the present disclosure;

FIG. 5 is a schematic diagram of an example distributed circuit model of a coupled resonator according to some embodiments of the present disclosure;

FIG. 6 is a schematic diagram of an example capacitance simulation result per unit length of KIM5 according to some embodiments of the present disclosure;

FIG. 7 is a schematic diagram of an example approximate distributed circuit model of a coupled resonator according to some embodiments of the present disclosure;

FIG. 8 is a schematic diagram of an example semi-analytical computation result according to some embodiments of the present disclosure;

FIG. 9 is a schematic diagram of an example capacitance simulation result per unit length of KIM5 according to some embodiments of the present disclosure;

FIG. 10 is a schematic diagram of an example semi-analytical computation result according to some embodiments of the present disclosure;

FIG. 11 is a structural block diagram of an example apparatus for adjusting a resonant cavity according to some embodiments of the present disclosure;

FIG. 12 is a structural block diagram of an example apparatus for adjusting a resonant cavity according to some embodiments of the present disclosure; and

FIG. 13 is a structural block diagram of an example computer terminal according

to some embodiments of the present disclosure.

### DETAILED DESCRIPTION

To make persons skilled in the art understand the solutions in the present disclosure better, the following describes the technical solutions in the embodiments of the present disclosure with reference to the accompanying drawings in the embodiments of the present disclosure. Apparently, the described embodiments are merely some but not all of the embodiments of the present disclosure. All other embodiments obtained by a person of ordinary skill in the art based on the embodiments of the present disclosure shall fall within the protection scope of the present disclosure.

It should be noted that the terms such as “first” and “second” in this specification, the claims, and the foregoing accompanying drawings of the present disclosure are intended to distinguish between similar objects rather than describe a particular sequence or a chronological order. It is to be understood that data used in this way is exchangeable in a proper case, so that the embodiments of the present disclosure described herein can be implemented in an order different from the order shown or described herein. Moreover, the terms “include”, “contain” and any other variants mean to cover the non-exclusive inclusion, for example, a process, method, system, product, or device that includes a list of steps or units is not necessarily limited to those expressly listed steps or units, but may include other steps or units not expressly listed or inherent to such a process, method, system, product, or device.

In some embodiments of the present disclosure, a way of computing the equivalent inductance of a coplanar waveguide is employed, and the equivalent inductance of the coplanar waveguide is computed based on the construction parameter of the coplanar waveguide by using a predetermined formula.

The coplanar waveguide refers to a microwave transmission line of the same plane on a dielectric base, which includes an intermediate signal line and the ground on both sides. When an electromagnetic wave propagates in the coplanar waveguide, electromagnetic energy is mainly concentrated between the intermediate signal line and the ground. The electromagnetic characteristics of the coplanar waveguide can be described with a standard transmission line model, which can usually be represented by two independent parameters, such as an effective dielectric constant and a characteristic impedance, or inductance per unit length and capacitance per unit length. These two representation ways are equivalent.

Because the equivalent inductance computed by employing the predetermined formula is equivalent to including the geometric inductance and the kinetic inductance, the influence of inaccurate estimation or unreasonable computation for the kinetic inductance caused by ignoring the presence of the kinetic inductance in a superconducting material is avoided. Then, the resonance frequency of the resonant cavity formed by the above-mentioned coplanar waveguide is determined according to the above-mentioned equivalent inductance. Resonant cavity usually refers to a metal cavity in which an electromagnetic field oscillates continuously. The resonant cavity can also be implemented by truncating both ends of the coplanar waveguide.

For the geometric inductance, the inductance per unit length in the standard transmission line model is the geometric inductance per unit length of the transmission line. The geometric inductance represents the ability of the transmission line to store magnetic field energy under a certain geometric shape, which is only related to the geometric shape and the dielectric material. In the superconducting material, due to the inertia and superconducting characteristics of the Cooper pairs, the material itself exhibits electromagnetic properties consistent with the inductance. This inductance reflected in the superconducting material is referred to as the kinetic inductance.

Also, because the unique kinetic inductance of the superconducting material is taken into account when computing the equivalent inductance, it can also be guaranteed that a resonance frequency functional relationship determined by the equivalent inductance is sufficiently accurate. That is, the resonance frequency of the resonant cavity can be adjusted accurately and efficiently by adjusting the construction parameter of the coplanar waveguide in the resonance frequency analytical function, thereby solving the technical problems of low adjustment efficiency and inaccurate results for a resonant cavity in a superconducting quantum device. When the solution of an equation can be expressed in an elementary function, it is an analytical solution. A semi-analytical solution is in between the analytical solution and a numerical solution. If a solution cannot be accurately expressed directly in an elementary function and only requires a simple numerical computation, it may be referred to as a semi-analytical solution.

According to some embodiments of the present disclosure, a method for adjusting a resonant cavity is provided. It should be noted that the steps shown in the flowchart in the figures can be performed in a computer system such as a set of computer executable instructions, and although a logical order is shown in the flowchart, in some cases, the steps shown or described can be performed in a different order.

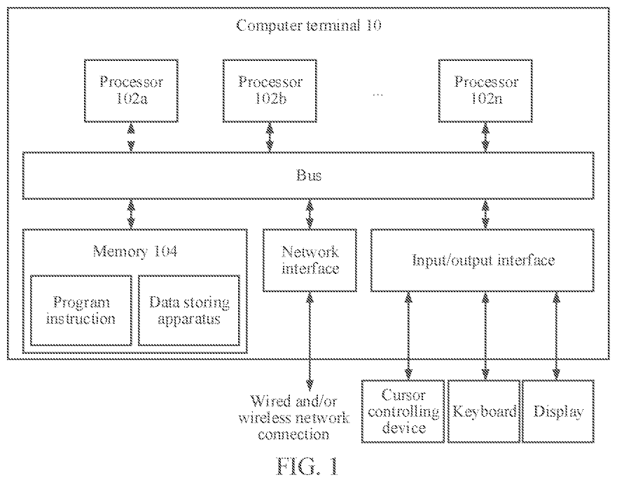

The method embodiments provided in some embodiments of the present disclosure can be performed in a mobile terminal, computer terminal, or similar computing apparatus. FIG. 1 shows a structural block diagram of hardware of an example computer terminal (or mobile device) for implementing a method for adjusting a resonant cavity. As shown in FIG. 1, a computer terminal 10 (or a mobile device) may include one or more processors (shown as processors 102a, 102b, . . . , 102n in the figure, which may include processing devices such as a microprocessor (MCU) or a programmable logic device (FPGA), but is not limited thereto), a memory 104 configured to store data, and a transmitting device used for communication functions. In addition, the computer terminal may further include: a display, an input/output interface (I/O interface), a universal serial bus (USB) port (which can be included as one of ports of a bus), a network interface, a power supply and/or a camera. A person of ordinary skill in the art will appreciate that the structure shown in FIG. 1 is merely illustrative, and does not limit the structure of the above-mentioned electronic apparatus. For example, the computer terminal 10 may further include more or fewer components than those shown in FIG. 1, or has a configuration different from that shown in FIG. 1.

It should be noted that one or more processors and/or other data processing circuits mentioned above can often be referred to as a “data processing circuit” herein. The data processing circuit may be embodied in whole or in part as software, hardware, firmware or any other combinations. Furthermore, the data processing circuit may be a single independent processing module, or combined in whole or in part into any of other elements in the computer terminal 10 (or mobile device). As involved in some embodiments of the present disclosure, the data processing circuit serves as a processor control (for example, the selection of a variable resistor terminal path connected to an interface).

The memory 104 can be configured to store software programs and modules of application software, such as a program instruction/data storing apparatus corresponding to the methods for adjusting the resonant cavity in some embodiments of the present disclosure. The processor(s) execute various function applications and data processing by running the software programs and modules stored in the memory 104, to implement a method for adjusting a resonant cavity in the above-mentioned application program. The memory 104 may include a high-speed random memory, and may also include a non-volatile memory, for example, one or more magnetic storage devices, a flash memory, or other nonvolatile solid-state memories. In some examples, the memory 104 may further include memories remotely disposed relative to the processor(s), and these remote memories may be connected to the computer terminal 10 via a network. Examples of the network include, but are not limited to, the Internet, an intranet, a local area network, a mobile communication network, or a combination thereof.

The transmitting device is configured to receive or send data via a network. The specific examples of the above-mentioned network may include a wireless network provided by a communication provider of the computer terminal 10. In an example, the transmitting device includes a network interface controller (NIC), and the NIC may be connected to other network devices via a base station, to communicate with the Internet. In an example, the transmitting device may be a radio frequency (RF) module, which is configured to communicate with the Internet in a wireless manner.

The display may be, for example, a touch screen type liquid crystal display (LCD), and the liquid crystal display enables a user to interact with a user interface of the computer terminal 10 (or mobile device).

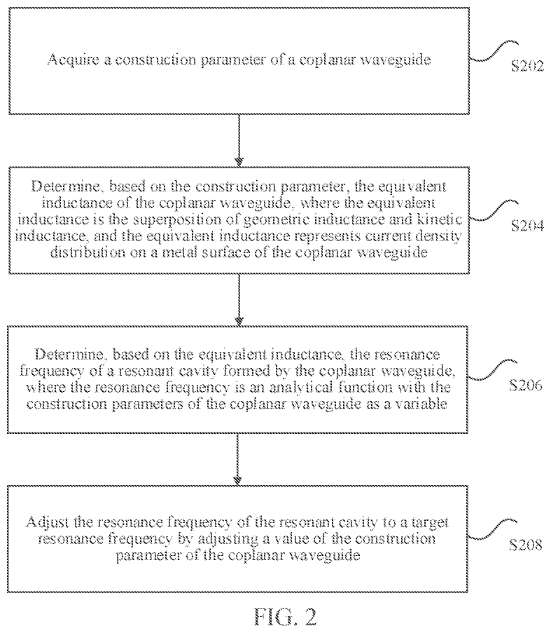

In the above-mentioned operating environment, the present disclosure provides a method for adjusting a resonant cavity as shown in FIG. 2. FIG. 2 is a flowchart of an example method for adjusting a resonant cavity, according to some embodiments of the present disclosure. As shown in FIG. 2, the method includes the following steps S202-S208.

In step S202, a construction parameter of a coplanar waveguide is acquired.

In step S204, the equivalent inductance of the coplanar waveguide is determined, based on the construction parameter. The equivalent inductance is the superposition of geometric inductance and kinetic inductance, and the equivalent inductance represents current density distribution on a metal surface of the coplanar waveguide.

In step S206, the resonance frequency of a resonant cavity formed by the coplanar waveguide is determined, based on the equivalent inductance. The resonance frequency is an analytical function with the construction parameter of the coplanar waveguide as an variable.

In step S208, the resonance frequency of the resonant cavity is adjusted to a target resonance frequency by adjusting a value of the construction parameter of the coplanar waveguide.

Through the above steps, by computing the equivalent inductance of the coplanar waveguide, and determining the resonance frequency of the resonant cavity based on the equivalent inductance to obtain the resonance frequency that is an analytical function with the construction parameter as a variable, because the computed equivalent inductance superposes the geometric inductance and the kinetic inductance, and the equivalent inductance represents the current density distribution on the metal surface of the coplanar waveguide, compared with the related art, in terms of only considering the geometric inductance, or considering the kinetic inductance, but not considering the current density distribution on the metal surface caused by the kinetic inductance, the problem of inaccurate resonance frequency determined due to the above cases is effectively avoided. Through the introduction of the above equivalent inductance, the accuracy of the resonance frequency of the resonant cavity is effectively improved, and the resonance frequency is the analytical function with the construction parameter as a variable. That is, the obtained resonance frequency is an accurate analytical solution, so that when the resonance frequency of the resonant cavity is adjusted subsequently, the resonance frequency of the resonant cavity can be accurately and efficiently adjusted by adjusting the value of the construction parameter of the coplanar waveguide, thereby solving the technical problems of low adjustment efficiency and inaccurate results for the resonant cavity of the superconducting quantum device.

In some embodiments, the operation of determining, based on the construction parameter, the equivalent inductance of the coplanar waveguide includes: determining, based on the construction parameter, equivalent inductance terms of the coplanar waveguide for position points in the width direction of the metal surface, where the equivalent inductance term is an analytical term with the construction parameter as the variable; and superposing the equivalent inductance terms of the coplanar waveguide for the position points in the width direction to obtain the equivalent inductance of the coplanar waveguide. The width direction of the metal surface is relative to the length of the metal surface of the coplanar waveguide. Because the equivalent inductance terms for different position points in the width direction are different, different current density distributions on the metal surface of the coplanar waveguide are reflected. The equivalent inductance terms for the position points in the width direction are superposed, and the obtained equivalent inductance of the coplanar waveguide also represents the current density distribution on the entire metal surface. It should be noted that the above-mentioned position points may be discrete or continuous. In some embodiments of the present disclosure, the position points are continuous, that is, a corresponding equivalent inductance term is an analytical term with the construction parameter as the variable, so that the obtained equivalent inductance of the coplanar waveguide is accurate.

In some embodiments, various ways can be employed for determining, based on the construction parameter, the equivalent inductance terms for the position points on the coplanar waveguide. For example, because the equivalent inductance is the superposition of the geometric inductance and the kinetic inductance, the corresponding equivalent inductance term can also be obtained by the superposition of a corresponding geometric inductance term and a kinetic inductance term. For example, the equivalent inductance terms can be obtained in the following ways: determining, based on the construction parameter, geometric inductance terms for the position points on the coplanar waveguide; determining, based on the construction parameter, kinetic inductance terms for the position points on the coplanar waveguide; and superposing the geometric inductance terms and the kinetic inductance terms to obtain the equivalent inductance terms. It should be noted that for a determined construction parameter, the kinetic inductance term at any position point on the coplanar waveguide may be the same. The parameters of the geometric inductance term can be determined based on the preparation process, that is, the process flow of the preparation process directly determines the parameters of the geometric inductance term. At the time of computing, any position point can be used as a fixed parameter of the design. Therefore, after the geometric inductance term and the kinetic inductance term are superposed, the obtained equivalent inductance term is represented as an analytical term with the construction parameter of the coplanar waveguide as the variable.

For the superconducting material, in addition to directly computing the geometric inductance with parameters such as the dielectric constant, line width, and line-to-ground spacing, there is also kinetic inductance caused by the unique properties of the superconducting material. In some embodiments, a change in current distribution due to the introduced kinetic inductance is considered, that is, the current density distribution on the metal surface of the entire coplanar waveguide is represented in manner of the equivalent inductance. In some embodiments, the geometric inductance term and the kinetic inductance term for each position point on the coplanar waveguide are superposed, which is equivalent to connecting two types of inductors in parallel at this position point. Thus, the equivalent inductance term for a corresponding position point is obtained.

In some embodiments, when the equivalent inductance terms of the coplanar waveguide for the position points in the width direction are superposed to obtain the equivalent inductance of the coplanar waveguide, in order to make the obtained equivalent inductance more accurate, the equivalent inductance on the position points can be integrated based on the position points to obtain the equivalent inductance of the coplanar waveguide. For example, the following integration method can be implemented: integrating, based on coordinate points, the equivalent inductance terms to obtain the equivalent inductance of the coplanar waveguide, under a condition that the position point is the coordinate point in the width direction of the metal surface of the coplanar waveguide by taking a center line of the coplanar waveguide as an origin. After the equivalent inductance term of the coplanar waveguide at each position point in the width direction, the equivalent inductance of the entire coplanar waveguide can be obtained by the integration to obtain a more accurate computation result of the equivalent inductance.

In some embodiments, when the equivalent inductance terms are integrated based on the coordinate points to obtain the equivalent inductance of the coplanar waveguide, according to different coordinates of the position points, in order to make the obtained integration result, that is, the equivalent inductance, more accurate, a piecewise integration method can be employed. For example, in a first direction in the width direction, it is divided into a first integration segment from the origin to half of the width of the metal surface, and a second integration segment from the starting position of a ground plate of the coplanar waveguide to an infinity position. The equivalent inductance terms are integrated based on the coordinate points in the first integration segment to obtain a first integration result, and the equivalent inductance terms are integrated based on the coordinate points in the second integration segment to obtain a second integration result. The first integration result and the second integration result are superposed to obtain a superposition result, and twice the superposition result is used as the equivalent inductance of the coplanar waveguide. Due to the symmetry of the coplanar waveguide, the integration result of one side can be determined directly, and then the entire equivalent inductance of the coplanar waveguide can be determined according to the symmetry to be twice thereof. In addition, corresponding integration results are obtained by employing different integration methods for different position points, which not only makes the integration results more accurate, but also requires less computation and is more efficient.

In some embodiments, when the resonance frequency of the resonant cavity formed by the coplanar waveguide is determined based on the equivalent inductance, various ways can be employed. For example, the following processing ways can be employed. The equivalent capacitance of the coplanar waveguide is determined based on the construction parameter. The phase velocity of an electromagnetic wave in the resonant cavity formed by the coplanar waveguide is determined based on the equivalent inductance and the equivalent capacitance. After that, the resonance frequency of the resonant cavity formed by the coplanar waveguide is determined based on the phase velocity and the length of the coplanar waveguide. The equivalent capacitance of the coplanar waveguide can be directly determined according to general geometric parameters, where the geometric parameters may be the width of the metal surface of the coplanar waveguide, the distance from the center line of the coplanar waveguide to an adjacent metal surface, a gap between the metal surface and a ground wireless large conductor, the length of the coplanar waveguide, the thickness of a coplanar waveguide substrate and so on. The phase velocity of the electromagnetic field propagating in the coplanar waveguide can be determined based on the equivalent capacitance and the equivalent inductance of the coplanar waveguide, and the resonance frequency of the resonant cavity formed by the coplanar waveguide can be determined according to the phase velocity and the length of the coplanar waveguide.

In some embodiments, because the resonance frequency is an analytical function with the construction parameter of the coplanar waveguide as the variable, when the value of the construction parameter changes, the resonance frequency of the resonant cavity will also change accordingly. Therefore, the resonance frequency of the resonant cavity can be effectively adjusted to the target resonance frequency by adjusting the value of the construction parameter of the coplanar waveguide. At the time of specific adjustments, the following simple and efficient adjustment methods can be employed. The phase velocity remains unchanged in a case that other geometric parameters, except the length of the coplanar waveguide, remain unchanged. Therefore, the target resonance frequency can be obtained by adjusting only the waveguide length, using a relationship between the resonance frequency, the waveguide length, and the phase velocity. That is, the resonance frequency of the resonant cavity is adjusted to the target resonance frequency by adjusting the value of the length of the coplanar waveguide in the construction parameter. After the resonance frequency of the resonant cavity formed by the coplanar waveguide is determined, because the obtained resonance frequency is essentially an analytical function based on the construction parameter of the coplanar waveguide, the resonance frequency of the resonant cavity can be adjusted by adjusting the construction parameter in the analytical function. Because the influence of the unique kinetic inductance of the superconducting material on the current density distribution of the metal surface has been fully considered when determining the analytical function, it can be guaranteed that the adjustment to the resonance frequency of the resonant cavity according to the analytical function can be sufficiently accurate.

In some embodiments, the construction parameter includes geometric parameters and material parameters. The geometric parameters mentioned above may be the width of the metal surface of the coplanar waveguide, the distance from the center line of the coplanar waveguide to the adjacent metal surface, the gap between the metal surface and a ground wireless large conductor, the length of the coplanar waveguide, the thickness of the coplanar waveguide substrate and so on. The material parameters mentioned above may be the material type of the coplanar waveguide substrate, the dielectric constant, the metal type of the metal surface of the coplanar waveguide and so on.

In some embodiments, after adjusting the resonance frequency of the resonant cavity to the target resonance frequency by adjusting the value of the construction parameter of the coplanar waveguide, the method further includes: measuring a target qubit by employing the resonant cavity with the target resonance frequency to obtain a measurement result. The target qubit includes a fluxonium qubit. It should be noted that when measuring the target qubit by employing the resonant cavity with the target resonance frequency, the method employed can be implemented based on the coupling between the resonant cavity and the target qubit.

As for qubits, in classical mechanical systems, the state of one bit is unique, while the quantum mechanics allows the qubit to be the superposition of two states at the same moment, which is the basic property of quantum computation. Physically, the qubit is a quantum state. Therefore, the qubit has the attributes of the quantum state. Due to the unique quantum attributes of the quantum state, the qubit has many features different from a classical bit, which is one of basic features of quantum information science.

Fluxonium refers to a superconducting qubit type, formed by a Josephson junction with parallel inductors and capacitors. This configuration has a large inductor (typically made of an array of a large number (about 100) of Josephson junctions or a high kinetic inductance material). Electrical energy EC corresponding to the capacitance, magnetic energy EL corresponding to the inductance, and Josephson energy EJ are close to each other (within about an order of magnitude).

A fluxonium-based qubit can be referred to as a “flux qubit.” The flux qubit includes a capacitor and several Josephson junctions, in which the capacitor is very small (e.g., EC being one order of magnitude smaller than EJ), and only several Josephson junctions exist, which can be approximately equivalent to a smaller inductor.

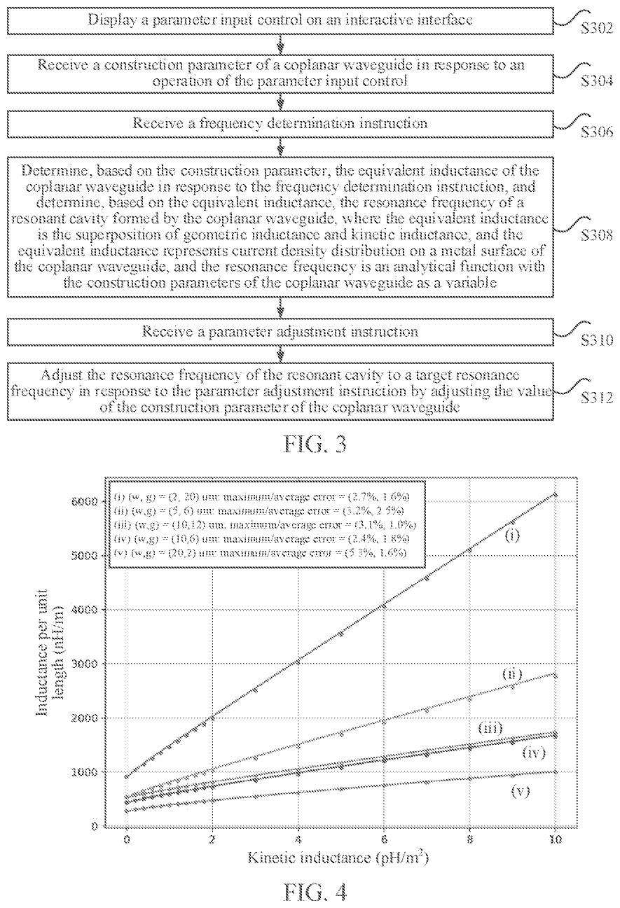

FIG. 3 is a flowchart of another example method for adjusting a resonant cavity according to some other embodiments of the present disclosure. As shown in FIG. 3, the method includes the following steps: S302-S312.

In step S302, a parameter input control is displayed on an interactive interface.

In step S304, a construction parameter of a coplanar waveguide is received, in response to an operation of the parameter input control.

In step S306, a frequency determination instruction is received.

In step S308, based on the construction parameter, the equivalent inductance of the coplanar waveguide is determined, in response to the frequency determination instruction, and based on the equivalent inductance, the resonance frequency of a resonant cavity formed by the coplanar waveguide is determined. The equivalent inductance is the superposition of geometric inductance and kinetic inductance, and the equivalent inductance represents current density distribution on a metal surface of the coplanar waveguide, and the resonance frequency is an analytical function with the construction parameter of the coplanar waveguide as the variable.

In step S310, a parameter adjustment instruction is received; and

In step S312, the resonance frequency of the resonant cavity is adjusted to a target resonance frequency in response to the parameter adjustment instruction by adjusting the value of the construction parameter of the coplanar waveguide.

Through the above steps, in response to input parameters of the coplanar waveguide, the frequency determination instruction, and the parameter adjustment instruction, it is realized that the resonance frequency of the resonant cavity formed by the coplanar waveguide can be accurately adjusted by adjusting the construction parameter of the coplanar waveguide. For the resonant cavity formed by the coplanar waveguide, a way of computing the equivalent inductance of the coplanar waveguide is employed, and the equivalent inductance of the coplanar waveguide is computed based on the construction parameter of the coplanar waveguide by using a predetermined formula. Because the equivalent inductance computed by employing the predetermined formula is equivalent to including the geometric inductance and the kinetic inductance, the influence of inaccurate estimation or unreasonable computation for the kinetic inductance caused by ignoring the presence of the kinetic inductance in a superconducting material is avoided. Then, the resonance frequency of the resonant cavity formed by the above-mentioned coplanar waveguide is determined according to the above-mentioned equivalent inductance. Also, because the unique kinetic inductance of the superconducting material is taken into account when computing the equivalent inductance, it can also be guaranteed that a resonance frequency functional relationship determined by the equivalent inductance is sufficiently accurate. That is, the resonance frequency of the resonant cavity can be adjusted accurately and efficiently by adjusting the construction parameter of the coplanar waveguide in the resonance frequency analytical function, thereby solving the technical problems of low adjustment efficiency and inaccurate results for the resonant cavity in the superconducting quantum device.

Based on the foregoing embodiments, the present disclosure proposes an implementation, which will be explained below.

In the related art, when analyzing common metal (materials without kinetic inductance properties), as long as a few parameters (such as the dielectric constant, the line width, the line-to-ground spacing, etc.) are known, the total inductance of the material can be calculated, as it only has geometric inductance but no kinetic inductance. However, for the superconducting quantum device (e.g., coplanar waveguide) with the kinetic inductance properties, the influence of the kinetic inductance on the resonant cavity cannot be quantitatively analyzed correctly when processing the computation of the parameters of the resonant cavity, resulting in time and labor-consuming simulation computation of the parameters of the resonant cavity.

In addition, when employing a simulation method for the inductance estimation and resonance frequency estimation of the resonant cavity, the simulation software simulates the entire device to obtain the resonance frequency. This method consumes computing power and is relatively slow. Furthermore, the equivalent inductance of the coplanar waveguide can also be computed according to other formulas. However, the computation methods in the related art are unreasonable, and when the thickness of a metal layer tends to be very thin, it is obvious that singularity problems occurs in the computation results thereof, leading to an inaccurate estimation.

For example, in the related art, a related assumption is made for the computation of the superposition of the geometric inductance and the kinetic inductance. For example, it is assumed that the current distribution is unchanged with and without kinetic inductance, and this assumption is obviously unreasonable. Because the current distribution will definitely change with the introduction of the kinetic inductance, in the related art, the superposition result of the geometric inductance and the kinetic inductance computed based on the above-mentioned assumption is inaccurate. In addition, some materials have kinetic inductance in a superconducting system, and there is no reasonable analytical solution for the computation of the equivalent inductance in the related art. Therefore, when it is necessary to compute the resonance frequency of the waveguide, numerical simulation is needed, and the entire computation is very complicated by employing the numerical simulation method.

Therefore, in the superconducting quantum device, the kinetic inductance is included. If the inductance of the superconducting material is computed by employing a method for analyzing the common metal, because only the geometric inductance is considered, the computation result is not sufficiently accurate, and the simulation computation process is time and labor-consuming. In addition, in the related art, the kinetic inductance of the superconducting material is generally computed on the assumption that the introduction of kinetic inductance will not influence the current density distribution on the metal surface, that is, the computation method employed is not sufficiently reasonable, resulting in inaccurate computation results thereof.

In view of the above technical problems, an implementation of the present disclosure is based on the distribution of the geometric inductance and the kinetic inductance of the superconducting material, and the geometric inductance and the kinetic inductance are superposed to obtain the equivalent inductance that can represent the current density distribution on the metal surface of the coplanar waveguide. The method will be introduced below.

In view of the above problems in the related art, it is an objective of the present disclosure to introduce the kinetic inductance to the analysis of the coplanar waveguide to analyze the electromagnetic characteristics (e.g., effective inductance and effective capacitance) of the coplanar waveguide of the superconducting quantum device, so as to realize the performance design of the resonant cavity. That is, in the superconducting system, the superconducting material may include the geometric inductance and the kinetic inductance, and the equivalent total inductance of the material can be obtained by superposing the geometric inductance and the kinetic inductance.

Based on the above-mentioned analysis, based on the distribution of geometric inductance and the distribution of the kinetic inductance of the superconducting material, the geometric inductance and the kinetic inductance are superposed to obtain the distribution of surface current density, and a corresponding representation way is obtained. In this representation way, it is equivalent to connecting two inductors in parallel to obtain the equivalent inductance of the material. Based on this, in an implementation of the present disclosure, according to a few parameters (e.g., several geometric and material parameters plus the kinetic inductance of a superconducting material) related to the waveguide in conventional materials, the analytical solution of the resonance frequency can be directly computed, and then the resonant cavity is designed accordingly. The equivalent inductance L computed in the above computation is derived from the surface current density distribution of a coating, thereby computing the resonance frequency of the resonant cavity.

For example, the method for adjusting the resonant cavity according to an implementation of the present disclosure can be implemented as follows.

Firstly, general parameters of the resonant cavity and the kinetic inductance of the coplanar waveguide are acquired. The coplanar waveguide is the way to implement the resonant cavity. After that, the resonance frequency of the resonant cavity is computed based on the multiple general parameters and the kinetic inductance. The structure of the resonant cavity is adjusted based on the resonance frequency and the target resonance frequency of the resonant cavity. The above-mentioned general parameters include: the dielectric constant of the substrate, the width of the center line of the coplanar waveguide, the distance from the center line of the coplanar waveguide to the adjacent metal surface, the length of the coplanar waveguide (the above are geometric parameters), and the kinetic inductance value of the superconducting material.

In some implementations, when the resonance frequency of the resonant cavity is computed based on the multiple general parameters and the kinetic inductance, it can be employed in the following way. The distribution of the geometric inductance is obtained through the general geometric parameters. The geometric inductance and the kinetic inductance are combined to obtain the total effective inductance by the above integration method. Furthermore, the total effective capacitance can be obtained directly through the general geometric parameters. The phase velocity of the electromagnetic field propagating in the coplanar waveguide can be obtained by using the equivalent inductance and the equivalent capacitance. The resonance frequency of the coplanar waveguide can be obtained by using the phase velocity and the length of the coplanar waveguide.

It should be noted that when the structure of the resonant cavity is adjusted based on the resonance frequency and the target resonance frequency of the resonant cavity, it can be employed in the following processing ways. When the resonance frequency of the coplanar waveguide is adjusted, only the length of the coplanar waveguide needs to be adjusted. The phase velocity remains unchanged in the condition that other geometric parameters remain unchanged. Therefore, the target resonance frequency can be obtained by adjusting only the waveguide length, using a relationship between the resonance frequency, the waveguide length, and the phase velocity.

In addition, the resonant cavity is a superconducting coplanar waveguide, which serves as a reading element of qubits. The frequency of the resonant cavity designed in the above-mentioned method is more accurate. Under the condition of high fidelity and without affecting the preservation of qubits, the frequency of the resonant cavity needs to be more accurate. Moreover, according to the equivalent inductance, the inductance or capacitance can be changed or the length of the coplanar waveguide can be adjusted by further changing the circuit design. The shorter the length, the higher the frequency, and then the frequency and impedance of the resonant cavity are adjusted.

In summary, according to the above-mentioned integration methods of the equivalent inductance, the equivalent inductance of the resonant cavity can be computed. Then, based on the construction parameter of the resonant cavity, an analytical solution of the resonance frequency of the resonant cavity is obtained, and the parameters of the waveguide are adjusted according to the target resonance frequency to implement the design of the resonant cavity. In addition, when conducting material analysis, it is sometimes unknown how large the kinetic inductance of the material is. At this time, other parameters of the coplanar waveguide can be measured, as well as the resonance frequency, and then the magnitude of the kinetic inductance is deduced in reverse.

Details of the above implementations will be explained separately below.

First, for the impedance and phase velocity of coplanar waveguide, in a case that the kinetic inductance is zero, the impedance of the coplanar waveguide can be expressed as follows.

$${Z}_{0} = \frac{60. π}{\sqrt{{ε}_{ewff}}} \frac{1.}{\frac{K ( k )}{K ( {k}^{′} )} + \frac{K ( k 1 )}{K ( k {1}^{′} )}} \\ {k}^{′} = \sqrt{1. - {k}^{2}} \\ k {1}^{′} = \sqrt{1. - k {1}^{2}} \\ k 1 = \frac{tanh ( \frac{π a}{4. h} )}{tanh ( \frac{π b}{4. h} )} \\ {ε}_{eff} = \frac{1. + {ε}_{r} \frac{K ( {k}^{′} )}{K ( k )} \frac{K ( k 1 )}{K ( k {1}^{′} )}}{1. + \frac{K ( {k}^{′} )}{K ( k )} \frac{K ( k 1 )}{K ( k {1}^{′} )}}$$

In this formula, a represents the width of the center line, b=a+2*gap, where gap represents a resonator gap and h represents the thickness of the substrate.

In summary, the property of an electric transmission line is determined jointly by the phase velocity vₚ and the impedance Z₀, where the phase velocity vₚ can be expressed as follows:

$${v}_{p} = \frac{C}{\sqrt{{ε}_{eff}}}$$

Second, for the geometric inductance and capacitance, the geometric inductance Lᵤ^{g} per unit length and capacitance Cᵤ^{g} per unit length can be directly determined by characteristic impedance Z₀ and the phase velocity vₚ. The specific formula is as follows.

$${L}_{u}^{g} = \frac{{Z}_{0}}{{v}_{p}} \\ {C}_{u}^{g} = \frac{1}{{Z}_{0} {v}_{p}}$$

Third, for the equivalent inductance, for the coplanar waveguide, its equivalent inductance includes geometric inductance and kinetic inductance, and its computation formula is as follows.

$${L}_{eff} = {( 2 {\int }_{0}^{a} \frac{1}{{l}_{g} ( x ) + {l}_{k}} dx )}^{- 1} + {( 2 {\int }_{b}^{∞} \frac{1}{{l}_{g} ( x ) + {l}_{k}} dx )}^{- 1} ,$$

where 2a represents the center distance of the resonant cavity width, b−a represents a resonant cavity gap, L_{eff} represents the equivalent inductance, l_{g} represents the geometric inductance, lₖ represents the kinetic inductance, and the geometric inductance can be expressed as the following functional relationship.

$${l}_{g} ( x ) = \frac{a {μ}_{0} K ( {k}^{′} )}{4} \sqrt{( 1 - \frac{{x}^{2}}{{a}^{2}} ) ( 1 - {k}^{2} \frac{{x}^{2}}{{a}^{2}} )}$$

FIG. 4 is a comparison schematic diagram of a computation result and a simulation result of kinetic inductance according to some embodiments of the present disclosure. As shown in FIG. 4, the results computed based on the above-mentioned formula are shown in the form of lines, and the kinetic inductance obtained by direct simulation of the coplanar waveguide is shown in the form of points.

Fourth, for the resonator length, the length of a resonator can be determined by the resonance frequency fᵣ and the phase velocity vₚ, and the formula is as follows.

$$L = n \frac{{v}_{p}}{{f}_{r}} ,$$

where n represents the number of wavelengths.

Fifth, for the feed line coupling, there are two ways to couple with a feed line, including: capacitive coupling and inductive coupling.

For the capacitive coupling, a half-wavelength resonator can be regarded as a parallel LC resonator, where:

$$C = \frac{1}{4 {f}_{r} {Z}_{0}} , and$$

$$L = \frac{{Z}_{0}}{{π}^{2} {f}_{r}} .$$

When the resonator is capacitively coupled with the feed line, effective coupling can be performed by connecting a capacitor C_{c} and a resistor

$$R = \frac{{Z}_{feed}}{2} ,$$

where Z_{feed} is the impedance of the feed line.

Assuming

$$\frac{1}{ω {C}_{c}} >> R ,$$

a series RC circuit can be equivalent to a parallel RC circuit, and the resistor and the capacitor after equivalence are as follows.

$${R}^{′} = \frac{1}{R {ω}^{2} {C}_{c}^{2}}$$

$$C = {C}_{c}$$

Therefore, additional capacitance is introduced to the coupling capacitance C_{c} by

$$\frac{{C}_{c}}{2 C} ,$$

thereby reducing the resonance frequency. The coupling quality factor can be expressed as follows.

$${Q}_{c} \approx {ω}_{r} {R}^{′} C = \frac{{C}_{c}}{C} \frac{1}{R {ω}_{r} {C}_{c}}$$

For the coupling capacitance estimation, the coupling capacitance can be computed by using a computation formula for infinite coplanar capacitance, and the formula is as follows.

$${C}_{c} = {ϵ}_{0} {ϵ}_{eff} \frac{K ( {k}^{′} )}{K ( k )} \cdot 1 ,$$

where l represents the length of the coplanar capacitor. It is assumed that the width of the coplanar capacitor is ω_{cpc}, and the distance between two lines is d_{cpc}. In addition,

$$k = \frac{{d}_{cpc} / 2}{{d}_{cpc} / 2 + {ω}_{cpc}} , {k}^{′} = \sqrt{1 - {k}^{2}} .$$

For the inductive coupling, a quarter short-circuit resonator can be regarded as a parallel LC resonator, where:

$$C = \frac{1}{8 {f}_{r} {Z}_{0}} , and$$

$$L = \frac{2 {Z}_{0}}{{π}^{2} {f}_{r}} .$$

When the resonator is inductively coupled with the feed line, effective coupling is performed through an inductor L₁, an inductor L₂, and a mutual inductance M, where the inductor L₂ is connected to a resistor with a resistance value of R_{FL}=2R_{load}.

The coupling quality factor is computed as follows:

$${Q}_{c} \approx \frac{{π}^{2}}{16} \frac{L}{M} \frac{{R}_{FL}}{{ω}_{0} M} ,$$

where L represents the effective inductance of a feed line resonator.

Sixth, for the semi-analytical model and simulation computation, in principle, prediction of the kinetic inductance should be correct and is independent of the value or amplitude of the kinetic inductance. The basic difference lies in the length of the resonator and the distance from the resonator to the feed line. This length will affect the coupling strength of the feed line to the ground and the ground to the feed line.

In an implementation of the present disclosure, by an analytical approach, the construction parameter of the coplanar waveguide is used to determine: a functional relationship between the resonance frequency of the resonant cavity formed by the coplanar waveguide and the construction parameter of the above-mentioned coplanar waveguide.

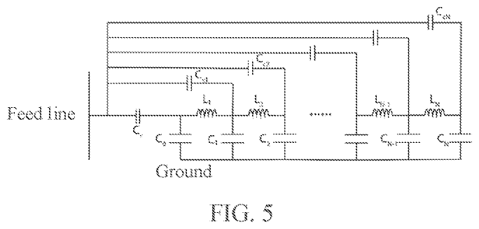

FIG. 5 is a schematic diagram of a distributed circuit model of a coupled resonator according to some embodiments of the present disclosure. As shown in FIG. 5, Cᵢ represents the capacitance to ground. For a long resonator, the capacitance per unit length can be computed as follows.

$${C}_{u} = 4 {ϵ}_{0} {ϵ}_{eff} \frac{K ( k )}{K ( {k}^{′} )} ,$$

where C_{ci} represents the coupling capacitance to the feed line, and there is usually no direct computation method. Lᵢ represents the uniformly distributed inductance, and the inductance per unit length can be computed by the following formula.

$${L}_{eff} = {( 2 {\int }_{0}^{a} \frac{1}{{l}_{g} ( x ) + {l}_{k}} dx )}^{- 1} + {( 2 {\int }_{b}^{∞} \frac{1}{{l}_{g} ( x ) + {l}_{k}} dx )}^{- 1}$$

$${l}_{g} ( x ) = \frac{a {μ}_{0} K ( {k}^{′} )}{4} \sqrt{( 1 - \frac{{x}^{2}}{{a}^{2}} ) ( 1 - {k}^{2} \frac{{x}^{2}}{{a}^{2}} )}$$

In this formula, 2a represents the center distance of the resonant cavity width, b−a represents the resonant cavity gap, L_{eff} represents the equivalent inductance, l_{g} represents the geometric inductance, and lₖ represents the kinetic inductance.

For a case that the capacitance distribution is higher and the kinetic inductance is hundreds of picohenry (pH), the length of the resonant cavity is longer than the width and the gap of the coplanar waveguide.

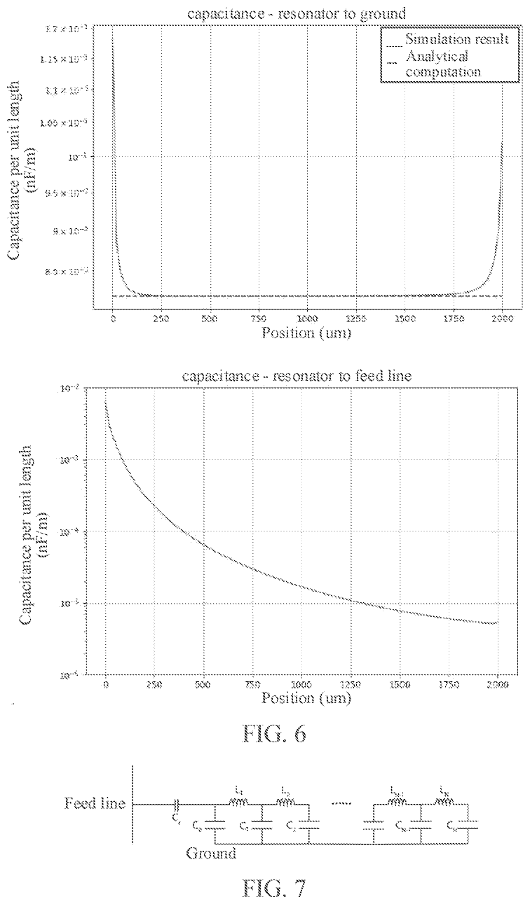

Taking K1M5 with a length of 2 mm, a gap of 50 um, and kinetic inductance of 240 nH per square meter as an example, the capacitance values per unit length of resonator to ground and resonator to feed line can be obtained through simulation. FIG. 6 is an example schematic diagram of a capacitance simulation result per unit length of KIM5 according to some embodiments of the present disclosure. As shown in FIG. 6, the upper portion is the capacitance to ground, and the lower portion is the capacitance to feed line. As can be seen from the upper diagram of FIG. 6, coupling with the ground is consistent, which is consistent with the analysis, except for two peaks appearing at both ends due to endpoints. As can be seen from the lower diagram of FIG. 6, the coupling with the feed line can be roughly regarded as a capacitor at the tail of the resonator.

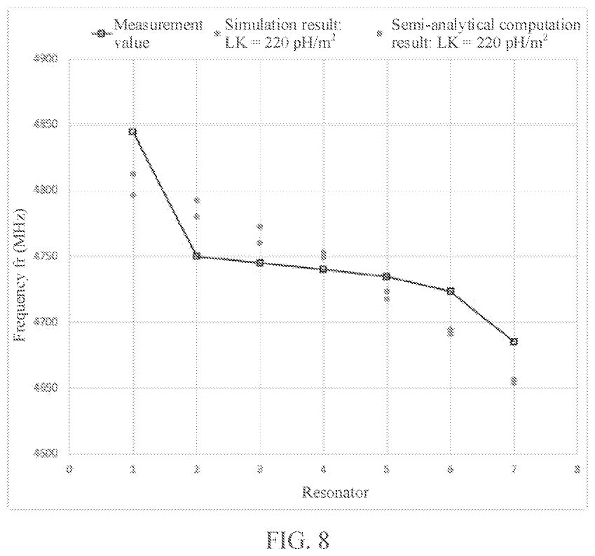

From this, an approximate circuit can be obtained as shown in FIG. 7. FIG. 7 is a schematic diagram of an example approximate distributed circuit model of a coupled resonator according to some embodiments of the present disclosure. Cᵢ, the capacitance to ground, can be determined based on the upper diagram of FIG. 6, and C_{c}, the capacitance to feed line, can be determined from the lower diagram of FIG. 6. FIG. 8 is a schematic diagram of an example semi-analytical computation result according to some embodiments of the present disclosure. As shown in FIG. 8, the analytical computation result is relatively close to the simulation computation result, but has a relatively great difference from the actual measurement result.

For a case that the capacitance distribution is extremely high and the kinetic inductance value is a few nanohenry (nH), the length of the resonant cavity is usually very short to meet the resonance frequency of a few gigahertz (GHz).

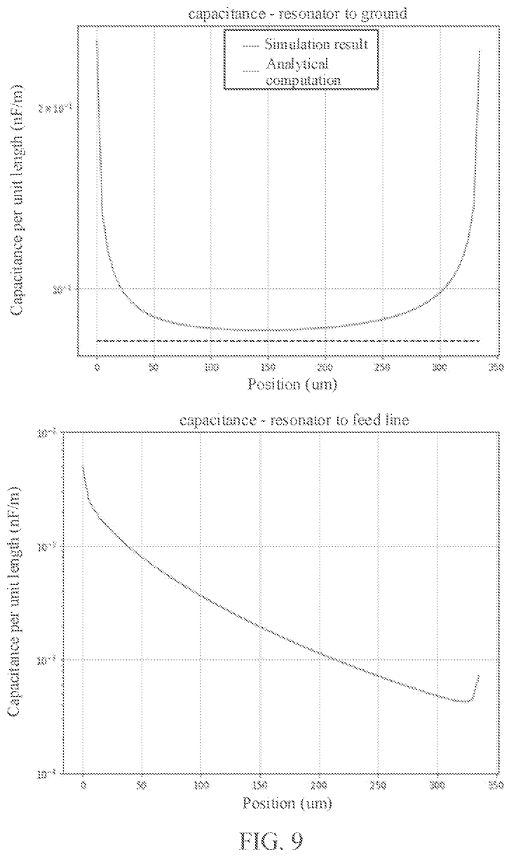

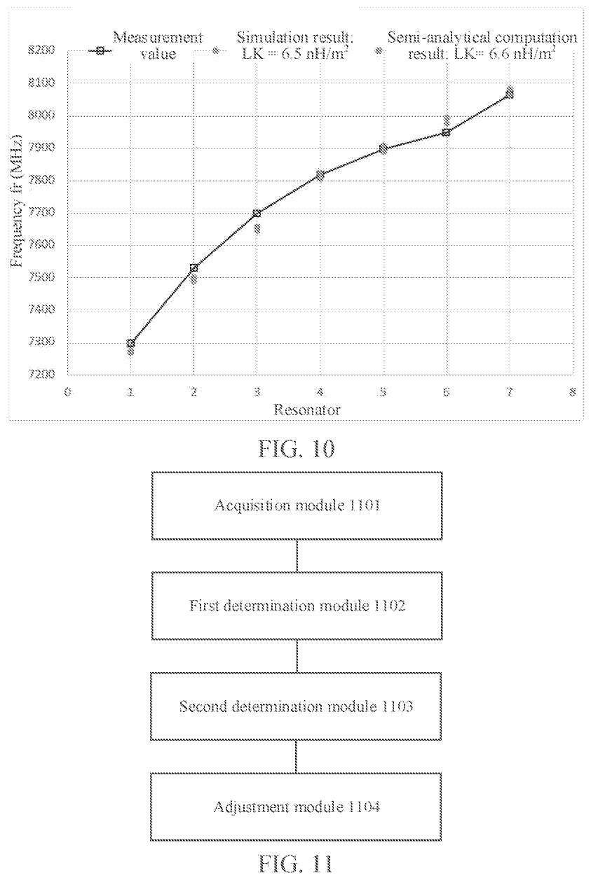

Taking K1M5 with a length of 340 um, a gap of 100 um, and kinetic inductance of 6.5 nH per square meter as an example, the coupling between the resonator and the feed line can be regarded as the distributed capacitance of the feed line, which effectively increases the capacitance of the transmission line, while the width/gap is smaller, and the thickness of the substrate needs to be considered. Therefore, in order to fit measurement data of 6.5 nH per square meter, a simplified model provides 8 to 9 nH. Therefore, some corrections are needed for this model. FIG. 9 is a schematic diagram of another example capacitance simulation result per unit length of KIM5 according to some embodiments of the present disclosure. As shown in FIG. 9, the upper portion is the capacitance to ground, and the lower portion is the capacitance to feed line. FIG. 10 is a schematic diagram of an example semi-analytical computation result according to some embodiments of the present disclosure. As shown in FIG. 10, the analytical computation result has very good consistency with the simulation computation result and the actual measurement result.

It should be noted that for each of the foregoing method embodiments, for ease of description, the method embodiments may be described as a series of action combinations, but a person skilled in the art should know that the present disclosure is not limited to an order of described actions, because according to embodiments of the present disclosure, some steps may be performed in another order or at the same time. In addition, a person skilled in the art should also know that all the embodiments described in this specification are exemplary embodiments, and the related actions and modules are not necessarily required in the present disclosure.

According to the descriptions in the foregoing implementations, a person skilled in the art can clearly understand that the methods for adjusting the resonant cavity according to the foregoing embodiments may be implemented by relying on software plus a necessary general hardware platform, and of course, may also be implemented by hardware. Based on this understanding, the technical solutions according to embodiments of the present disclosure essentially, or the part contributing to the conventional solutions, may be embodied in the form of a software product. The computer software product is stored in a computer-readable storage medium (such as an ROM/RAM, a magnetic disk, or an optical disc) including several instructions for making a terminal device (which may be a mobile phone, a computer, a server, a network device, or the like) to perform the methods described in the embodiments of the present disclosure.

According to some embodiments of the present disclosure, an apparatus for implementing the methods for adjusting the resonant cavity is provided. FIG. 11 is a structural block diagram of an example apparatus for adjusting a resonant cavity according to some embodiments of the present disclosure. As shown in FIG. 11, the apparatus includes: an acquisition module 1101, a first determination module 1102, a second determination module 1103 and an adjustment module 1104. The apparatus will be explained below.

The acquisition module 1101 is configured to acquire a construction parameter of a coplanar waveguide. The first determination module 1102 is connected to the above-mentioned acquisition module 1101, and is configured to determine, based on the construction parameter, the equivalent inductance of the coplanar waveguide. The equivalent inductance is the superposition of geometric inductance and kinetic inductance, and the equivalent inductance represents current density distribution on a metal surface of the coplanar waveguide. The second determination module 1103 is connected to the above-mentioned first determination module 1102, and is configured to determine, based on the equivalent inductance, the resonance frequency of a resonant cavity formed by the coplanar waveguide. The resonance frequency is an analytical function with the construction parameter of the coplanar waveguide as a variable. The adjustment module 1104 is connected to the above-mentioned second determination module 1103, and is configured to adjust the resonance frequency of the resonant cavity to a target resonance frequency by adjusting a value of the construction parameter of the coplanar waveguide.

Here, it should be noted that the above-mentioned acquisition module 1101, first determination module 1102, second determination module 1103 and adjustment module 1104 correspond to steps S202 to S208 in the embodiments of FIG. 2. Examples and application scenarios implemented by these four modules and the corresponding steps are the same, but are not limited to the content disclosed in the embodiments of FIG. 2. It should be noted that the above-mentioned modules can be run as part of the apparatus in the computer terminal 10 provided in the embodiments of FIG. 1.

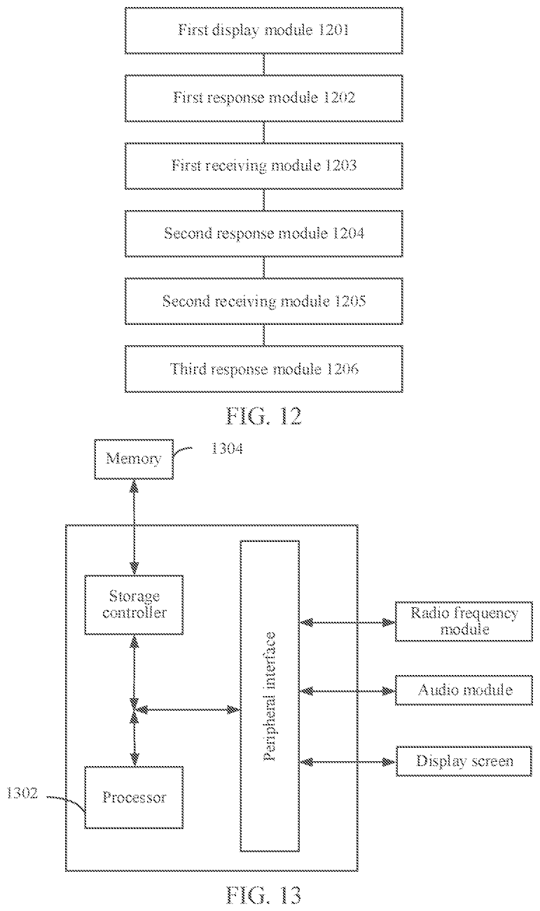

According to some embodiments of the present disclosure, another apparatus for implementing the methods for adjusting the resonant cavity is provided. FIG. 12 is a structural block diagram of another example apparatus for adjusting a resonant cavity according to some embodiments of the present disclosure. As shown in FIG. 12, the apparatus includes a first display module 1201, a first response module 1202, a first receiving module 1203, a second response module 1204, a second receiving module 1205, and a third response module 1206. The apparatus will be explained below.

The first display module 1201 is configured to display a parameter input control on an interactive interface. The first response module 1202 is connected to the above-mentioned first display module 1201, and is configured to receive a construction parameter of a coplanar waveguide in response to an operation of the parameter input control. The first receiving module 1203 is connected to the above-mentioned first response module 1202, and is configured to receive a frequency determination instruction. The second response module 1204 is connected to the above-mentioned first receiving module 1203, and is configured to determine, based on the construction parameter, the equivalent inductance of the coplanar waveguide in response to the frequency determination instruction, and determine, based on the equivalent inductance, the resonance frequency of a resonant cavity formed by the coplanar waveguide. The equivalent inductance is the superposition of geometric inductance and kinetic inductance, and the equivalent inductance represents current density distribution on a metal surface of the coplanar waveguide, and the resonance frequency is an analytical function with the construction parameter of the coplanar waveguide as the variable. The second receiving module 1205 is connected to the above-mentioned second response module 1204, and is configured to receive a parameter adjustment instruction. The third response module 1206 is connected to the above-mentioned second receiving module 1205, and is configured to adjust the resonance frequency of the resonant cavity to a target resonance frequency in response to the parameter adjustment instruction by adjusting a value of the construction parameter of the coplanar waveguide.

Here, it should be noted that the above-mentioned first display module 1201, first response module 1202, first receiving module 1203, second response module 1204, second receiving module 1205 and third response module 1206 correspond to steps S302 to S312 in the embodiments of FIG. 3. Examples and application scenarios implemented by these six modules and the corresponding steps are the same, but are not limited to the content disclosed in the embodiments of FIG. 3. It should be noted that the above-mentioned modules can be run as part of the apparatus in the computer terminal 10 provided in the embodiments of FIG. 1.

The embodiments of the present disclosure can provide a computer terminal. The computer terminal may be any computer terminal device in a computer terminal group. Optionally, in some embodiments, the above-mentioned computer terminal can also be replaced with terminal devices such as a mobile terminal.

Optionally, in some embodiments, the above-mentioned computer terminal can be located on at least one of multiple network devices of the computer network.

In some embodiments, the above-mentioned computer terminal can execute program codes of an application program for the following steps of the methods for adjusting the resonant cavity: acquiring a construction parameter of a coplanar waveguide; determining, based on the construction parameter, the equivalent inductance of the coplanar waveguide, where the equivalent inductance is the superposition of geometric inductance and kinetic inductance, and the equivalent inductance represents current density distribution on a metal surface of the coplanar waveguide; determining, based on the equivalent inductance, the resonance frequency of a resonant cavity formed by the coplanar waveguide, where the resonance frequency is an analytical function with the construction parameter of the coplanar waveguide as a variable; and adjusting the resonance frequency of the resonant cavity to a target resonance frequency by adjusting the value of the construction parameter of the coplanar waveguide.

Optionally, FIG. 13 is a structural block diagram of an example computer terminal according to some embodiments of the present disclosure. As shown in FIG. 13, the computer terminal may include one or more (only one shown in the figure) processors 1301, a memory 1302, etc.

The memory can be configured to store software programs and modules, such as program instructions/modules corresponding to the methods and apparatus for adjusting the resonant cavity in some embodiments of the present disclosure. The one or more processors execute various function applications and data processing by running the software programs and modules stored in the memory, that is, implement the above-mentioned methods for adjusting the resonant cavity. The memory may include a high-speed random memory, and may also include a non-volatile memory, for example, one or more magnetic storing devices, a flash memory, or other nonvolatile solid-state memories. In some examples, the memory may further include memories remotely disposed relative to the processor, and these remote memories may be connected to the computer terminal via a network. Examples of the network include, but are not limited to, the Internet, an intranet, a local area network, a mobile communication network, and a combination thereof.

The processor(s) can call the information and application programs stored in memory by the transmitting device to perform the following operations: acquiring a construction parameter of a coplanar waveguide; determining, based on the construction parameter, the equivalent inductance of the coplanar waveguide, where the equivalent inductance is the superposition of geometric inductance and kinetic inductance, and the equivalent inductance represents current density distribution on a metal surface of the coplanar waveguide; determining, based on the equivalent inductance, the resonance frequency of a resonant cavity formed by the coplanar waveguide, where the resonance frequency is an analytical function with the construction parameter of the coplanar waveguide as a variable; and adjusting the resonance frequency of the resonant cavity to a target resonance frequency by adjusting the value of the construction parameter of the coplanar waveguide.

Optionally, the above-mentioned processor(s) can further perform the methods for adjusting the resonant cavity according to the foregoing embodiments.

A person of ordinary skill in the art can understand that, the structure shown in FIG. 13 is only an example. The computer terminal may be a terminal device such as a smartphone (such as an Android mobile phone or an iOS mobile phone), a tablet computer, a palmtop computer, a Mobile Internet Device (MID), or a PAD. In FIG. 13, the structure of the above-mentioned electronic apparatus is not limited. For example, the computer terminal may further include more or fewer components (such as a network interface and a display device) than those shown in FIG. 13, or has a configuration different from that shown in FIG. 13.

A person of ordinary skill in the art can understand that all or some of the steps of various methods in the foregoing embodiments may be implemented by a program instructing related hardware of the terminal device. The program can be stored in a computer-readable storage medium. The computer-readable storage medium may include: a flash drive, a read-only memory (ROM), a random access memory (RAM), a magnetic disk, an optical disc or the like.

The embodiments of the present disclosure further provide a computer-readable storage medium. Optionally, in some embodiments, the above-mentioned computer-readable storage medium can be configured to store the program codes executed by the methods for adjusting the resonant cavity provided in embodiments of FIG. 1-FIG. 10.

Optionally, in some embodiments, the above-mentioned computer-readable storage medium can be located in any computer terminal of a computer terminal group, or located in any mobile terminal of a mobile terminal group in a computer network.

Optionally, in some embodiments, the computer-readable storage medium is configured to store the program codes used for performing the following operations: acquiring a construction parameter of a coplanar waveguide; determining, based on the construction parameter, the equivalent inductance of the coplanar waveguide, where the equivalent inductance is the superposition of geometric inductance and kinetic inductance, and the equivalent inductance represents current density distribution on a metal surface of the coplanar waveguide; determining, based on the equivalent inductance, the resonance frequency of a resonant cavity formed by the coplanar waveguide, where the resonance frequency is an analytical function with the construction parameter of the coplanar waveguide as a variable; and adjusting the resonance frequency of the resonant cavity to a target resonance frequency by adjusting the value of the construction parameter of the coplanar waveguide.

Optionally, in some embodiments, the computer-readable storage medium is further configured to store the methods for adjusting the resonant cavity according to foregoing embodiments and implementations.

The sequence numbers of the embodiments of the present disclosure are merely for the description purpose and do not imply the preference among the embodiments.

In the foregoing embodiments of the present disclosure, the descriptions of the embodiments have different focuses. For a part that is not detailed in some embodiments, reference may be made to the related description of other embodiments.

In the several embodiments provided in the present disclosure, it should be understood that the disclosed technical content may be implemented in other ways. The apparatus embodiments described above are merely examples. For example, the division of the units is merely the division of logic functions, and may use other division ways during actual implementation. For example, a plurality of units or components may be combined, or may be integrated into another system, or some features may be omitted or not performed. In addition, the coupling, or direct coupling, or communication connection between the shown or discussed components may be the indirect coupling or communication connection by some interfaces, units, or modules, and may be electrical or of other forms.

The units described as separate components may or may not be physically separated, and the components shown as units may or may not be physical units, and may be located in one place or may be distributed over a plurality of network units. Some or all of the units may be selected according to actual needs to achieve the objectives of the solutions of the embodiments.

In addition, functional units in the embodiments of the present disclosure may be integrated into one processing unit, or each of the units may be physically separated, or two or more units may be integrated into one unit. The integrated unit may be implemented in the form of hardware, or may be implemented in a form of a software functional unit.

When the integrated unit is implemented in the form of a software functional unit and sold or used as an independent product, the integrated unit may be stored in a computer-readable storage medium. Based on this understanding, the technical solutions of the present disclosure essentially, or the part contributing to the conventional solutions, or all or some of the technical solutions may be embodied in the form of a software product. The computer software product is stored in the computer-readable storage medium, and includes several instructions for making one or more computer devices (which may be a personal computer, a server, a network device, or the like) to perform all or some of the operations of the methods described in the embodiments of the present disclosure. The aforementioned computer-readable storage medium includes various media that can store the program codes, such as a USB disk, a read-only memory (ROM), a random access memory (RAM), a portable hard disk, a magnetic disk or an optical disc.

The embodiments may further be described using the following clauses:
1: A method for adjusting a resonant cavity, comprising: acquiring a construction parameter of a coplanar waveguide; determining, based on the construction parameter, an equivalent inductance of the coplanar waveguide, wherein the equivalent inductance is a superposition of geometric inductance and kinetic inductance, and the equivalent inductance represents current density distribution on a metal surface of the coplanar waveguide; determining, based on the equivalent inductance, a resonance frequency of the resonant cavity formed by the coplanar waveguide, wherein the resonance frequency is an analytical function with the construction parameter of the coplanar waveguide as a variable; and adjusting the resonance frequency of the resonant cavity to a target resonance frequency by adjusting a value of the construction parameter of the coplanar waveguide.
2: The method of clause 1, wherein the determining, based on the construction parameter, the equivalent inductance of the coplanar waveguide comprises: determining, based on the construction parameter, equivalent inductance terms of the coplanar waveguide for position points in a width direction of the metal surface, wherein the equivalent inductance term is an analytical term with the construction parameter as the variable; and superposing the equivalent inductance terms of the coplanar waveguide for the position points in the width direction to obtain the equivalent inductance of the coplanar waveguide.
3: The method of clause 2, wherein the determining, based on the construction parameter, the equivalent inductance terms for the position points on the coplanar waveguide comprises: determining, based on the construction parameter, geometric inductance terms for the position points on the coplanar waveguide; determining kinetic inductance terms for the position points on the coplanar waveguide; and superposing the geometric inductance terms and the kinetic inductance terms to obtain the equivalent inductance terms.
4: The method of clause 2 or clause 3, wherein the superposing the equivalent inductance terms of the coplanar waveguide for the position points in the width direction to obtain the equivalent inductance of the coplanar waveguide comprises: integrating, based on coordinate points, the equivalent inductance terms to obtain the equivalent inductance of the coplanar waveguide, under a condition that the position point is the coordinate point in the width direction of the metal surface of the coplanar waveguide by taking a center line of the coplanar waveguide as an origin.
5: The method of clause 4, wherein the integrating, based on the coordinate points, the equivalent inductance terms to obtain the equivalent inductance of the coplanar waveguide comprises: dividing from the origin to half of a width of the metal surface into a first integration segment, and dividing from a starting position of a ground plate of the coplanar waveguide to an infinity position into a second integration segment, in a first direction in the width direction; integrating, based on the coordinate points in the first integration segment, the equivalent inductance terms to obtain a first integration result, and integrating, based on the coordinate points in the second integration segment, the equivalent inductance terms to obtain a second integration result; and superposing the first integration result and the second integration result to obtain a superposition result, and using twice the superposition result as the equivalent inductance of the coplanar waveguide.
6: The method of any of clauses 1-5, wherein the determining, based on the equivalent inductance, the resonance frequency of the resonant cavity formed by the coplanar waveguide comprises: determining, based on the construction parameter, an equivalent capacitance of the coplanar waveguide; determining, based on the equivalent inductance and the equivalent capacitance, a phase velocity of an electromagnetic wave in the resonant cavity formed by the coplanar waveguide; and determining, based on the phase velocity and a length of the coplanar waveguide in the construction parameter, the resonance frequency of the resonant cavity formed by the coplanar waveguide.
7: The method of any of clauses 1-6, wherein the adjusting the resonance frequency of the resonant cavity to the target resonance frequency by adjusting the value of the construction parameter of the coplanar waveguide comprises: adjusting the resonance frequency of the resonant cavity to the target resonance frequency by adjusting the value of a length of the coplanar waveguide in the construction parameter.
8: The method of any of clauses 1-7, wherein the construction parameter comprises a geometric parameter and a material parameter.
9: The method of clause 8, wherein after the adjusting the resonance frequency of the resonant cavity to the target resonance frequency by adjusting the value of the construction parameter of the coplanar waveguide, the method further comprises: measuring a target qubit by employing the resonant cavity with the target resonance frequency to obtain a measurement result, wherein the target qubit comprises: a fluxonium qubit.
10: A method for adjusting a resonant cavity, comprising: displaying a parameter input control on an interactive interface; receiving a construction parameter of a coplanar waveguide in response to an operation to the parameter input control; receiving a frequency determination instruction; determining, based on the construction parameter, an equivalent inductance of the coplanar waveguide in response to the frequency determination instruction, and determining, based on the equivalent inductance, a resonance frequency of the resonant cavity formed by the coplanar waveguide, wherein the equivalent inductance is a superposition of geometric inductance and kinetic inductance, and the equivalent inductance represents current density distribution on a metal surface of the coplanar waveguide, and the resonance frequency is an analytical function with the construction parameter of the coplanar waveguide as a variable; receiving a parameter adjustment instruction; and adjusting the resonance frequency of the resonant cavity to a target resonance frequency in response to the parameter adjustment instruction by adjusting a value of the construction parameter of the coplanar waveguide.
11: An apparatus for adjusting a resonant cavity, comprising: an acquisition module, configured to acquire a construction parameter of a coplanar waveguide; a first determination module, configured to determine, based on the construction parameter, an equivalent inductance of the coplanar waveguide, wherein the equivalent inductance is a superposition of geometric inductance and kinetic inductance, and the equivalent inductance represents current density distribution on a metal surface of the coplanar waveguide; a second determination module, configured to determine, based on the equivalent inductance, a resonance frequency of the resonant cavity formed by the coplanar waveguide, wherein the resonance frequency is an analytical function with the construction parameter of the coplanar waveguide as a variable; and an adjustment module, configured to adjust the resonance frequency of the resonant cavity to a target resonance frequency by adjusting a value of the construction parameter of the coplanar waveguide.
12: A non-transitory computer-readable storage medium storing a program that is executable by a device to cause the device to perform operations comprising: acquiring a construction parameter of a coplanar waveguide; determining, based on the construction parameter, an equivalent inductance of the coplanar waveguide, wherein the equivalent inductance is a superposition of geometric inductance and kinetic inductance, and the equivalent inductance represents current density distribution on a metal surface of the coplanar waveguide; determining, based on the equivalent inductance, a resonance frequency of a resonant cavity formed by the coplanar waveguide, wherein the resonance frequency is an analytical function with the construction parameter of the coplanar waveguide as a variable; and adjusting the resonance frequency of the resonant cavity to a target resonance frequency by adjusting a value of the construction parameter of the coplanar waveguide.
13: The non-transitory computer-readable storage medium of clause 12, wherein the operation of determining, based on the construction parameter, the equivalent inductance of the coplanar waveguide comprises: determining, based on the construction parameter, equivalent inductance terms of the coplanar waveguide for position points in a width direction of the metal surface, wherein the equivalent inductance term is an analytical term with the construction parameter as the variable; and superposing the equivalent inductance terms of the coplanar waveguide for the position points in the width direction to obtain the equivalent inductance of the coplanar waveguide.
14: The non-transitory computer-readable storage medium of clause 13, wherein the operation of determining, based on the construction parameter, the equivalent inductance terms for the position points on the coplanar waveguide comprises: determining, based on the construction parameter, geometric inductance terms for the position points on the coplanar waveguide; determining kinetic inductance terms for the position points on the coplanar waveguide; and superposing the geometric inductance terms and the kinetic inductance terms to obtain the equivalent inductance terms.
15: The non-transitory computer-readable storage medium of clause 13 or clause 14, wherein the operation of superposing the equivalent inductance terms of the coplanar waveguide for the position points in the width direction to obtain the equivalent inductance of the coplanar waveguide comprises: integrating, based on coordinate points, the equivalent inductance terms to obtain the equivalent inductance of the coplanar waveguide, under a condition that the position point is the coordinate point in the width direction of the metal surface of the coplanar waveguide by taking a center line of the coplanar waveguide as an origin.
16: The non-transitory computer-readable storage medium of clause 15, wherein the operation of integrating, based on the coordinate points, the equivalent inductance terms to obtain the equivalent inductance of the coplanar waveguide comprises: dividing from the origin to half of a width of the metal surface into a first integration segment, and dividing from a starting position of a ground plate of the coplanar waveguide to an infinity position into a second integration segment, in a first direction in the width direction; integrating, based on the coordinate points in the first integration segment, the equivalent inductance terms to obtain a first integration result, and integrating, based on the coordinate points in the second integration segment, the equivalent inductance terms to obtain a second integration result; and superposing the first integration result and the second integration result to obtain a superposition result, and using twice the superposition result as the equivalent inductance of the coplanar waveguide.
17: The non-transitory computer-readable storage medium of any of clauses 12-16, wherein the operation of determining, based on the equivalent inductance, the resonance frequency of the resonant cavity formed by the coplanar waveguide comprises: determining, based on the construction parameter, an equivalent capacitance of the coplanar waveguide; determining, based on the equivalent inductance and the equivalent capacitance, a phase velocity of an electromagnetic wave in the resonant cavity formed by the coplanar waveguide; and determining, based on the phase velocity and a length of the coplanar waveguide in the construction parameter, the resonance frequency of the resonant cavity formed by the coplanar waveguide.
18: The non-transitory computer-readable storage medium of any of clauses 12-17, wherein the operation of adjusting the resonance frequency of the resonant cavity to the target resonance frequency by adjusting the value of the construction parameter of the coplanar waveguide comprises: adjusting the resonance frequency of the resonant cavity to the target resonance frequency by adjusting the value of a length of the coplanar waveguide in the construction parameter.
19: The non-transitory computer-readable storage medium of any of clauses 12-18, wherein the construction parameter comprises a geometric parameter and a material parameter.
20: The non-transitory computer-readable storage medium of clause 19, wherein after the operation of adjusting the resonance frequency of the resonant cavity to the target resonance frequency by adjusting the value of the construction parameter of the coplanar waveguide, the operations further comprise: measuring a target qubit by employing the resonant cavity with the target resonance frequency to obtain a measurement result, wherein the target qubit comprises: a fluxonium qubit.
21: A computer device, comprising: a memory configured to store a computer program; and one or more processors configured to run the computer program stored in the memory, to cause the computer device to execute operations comprising: acquiring a construction parameter of a coplanar waveguide; determining, based on the construction parameter, an equivalent inductance of the coplanar waveguide, wherein the equivalent inductance is a superposition of geometric inductance and kinetic inductance, and the equivalent inductance represents current density distribution on a metal surface of the coplanar waveguide; determining, based on the equivalent inductance, a resonance frequency of a resonant cavity formed by the coplanar waveguide, wherein the resonance frequency is an analytical function with the construction parameter of the coplanar waveguide as a variable; and adjusting the resonance frequency of the resonant cavity to a target resonance frequency by adjusting a value of the construction parameter of the coplanar waveguide.
22: The computer device of clause 21, wherein the operation of determining, based on the construction parameter, the equivalent inductance of the coplanar waveguide comprises: determining, based on the construction parameter, equivalent inductance terms of the coplanar waveguide for position points in a width direction of the metal surface, wherein the equivalent inductance term is an analytical term with the construction parameter as the variable; and superposing the equivalent inductance terms of the coplanar waveguide for the position points in the width direction to obtain the equivalent inductance of the coplanar waveguide.
23: The computer device of clause 22, wherein the operation of determining, based on the construction parameter, the equivalent inductance terms for the position points on the coplanar waveguide comprises: determining, based on the construction parameter, geometric inductance terms for the position points on the coplanar waveguide; determining kinetic inductance terms for the position points on the coplanar waveguide; and superposing the geometric inductance terms and the kinetic inductance terms to obtain the equivalent inductance terms.
24: The computer device of clause 22 or clause 23, wherein the operation of superposing the equivalent inductance terms of the coplanar waveguide for the position points in the width direction to obtain the equivalent inductance of the coplanar waveguide comprises: integrating, based on coordinate points, the equivalent inductance terms to obtain the equivalent inductance of the coplanar waveguide, under a condition that the position point is the coordinate point in the width direction of the metal surface of the coplanar waveguide by taking a center line of the coplanar waveguide as an origin.
25: The computer device of clause 24, wherein the operation of integrating, based on the coordinate points, the equivalent inductance terms to obtain the equivalent inductance of the coplanar waveguide comprises: dividing from the origin to half of a width of the metal surface into a first integration segment, and dividing from a starting position of a ground plate of the coplanar waveguide to an infinity position into a second integration segment, in a first direction in the width direction; integrating, based on the coordinate points in the first integration segment, the equivalent inductance terms to obtain a first integration result, and integrating, based on the coordinate points in the second integration segment, the equivalent inductance terms to obtain a second integration result; and superposing the first integration result and the second integration result to obtain a superposition result, and using twice the superposition result as the equivalent inductance of the coplanar waveguide.
26: The computer device of any of clauses 21-25, wherein the operation of determining, based on the equivalent inductance, the resonance frequency of the resonant cavity formed by the coplanar waveguide comprises: determining, based on the construction parameter, an equivalent capacitance of the coplanar waveguide; determining, based on the equivalent inductance and the equivalent capacitance, a phase velocity of an electromagnetic wave in the resonant cavity formed by the coplanar waveguide; and determining, based on the phase velocity and a length of the coplanar waveguide in the construction parameter, the resonance frequency of the resonant cavity formed by the coplanar waveguide.
27: The computer device of any of clauses 21-26, wherein the operation of adjusting the resonance frequency of the resonant cavity to the target resonance frequency by adjusting the value of the construction parameter of the coplanar waveguide comprises: adjusting the resonance frequency of the resonant cavity to the target resonance frequency by adjusting the value of a length of the coplanar waveguide in the construction parameter.
28: The computer device of any of clauses 21-27, wherein the construction parameter comprises a geometric parameter and a material parameter.
29: The computer device of clause 28, wherein after the operation of adjusting the resonance frequency of the resonant cavity to the target resonance frequency by adjusting the value of the construction parameter of the coplanar waveguide, the operations further comprise: measuring a target qubit by employing the resonant cavity with the target resonance frequency to obtain a measurement result, wherein the target qubit comprises: a fluxonium qubit.

The foregoing descriptions are exemplary implementations of the present disclosure. It is noted that a person of ordinary skill in the art may make some improvements and modifications without departing from the principle of the present disclosure and the improvements and modifications shall fall within the protection scope of the present disclosure.

What is claimed is:

1. A method for adjusting a resonant cavity, comprising:
acquiring a construction parameter of a coplanar waveguide;
determining, based on the construction parameter, an equivalent inductance of the coplanar waveguide, wherein the equivalent inductance is a superposition of geometric inductance and kinetic inductance, and the equivalent inductance represents current density distribution on a metal surface of the coplanar waveguide;
determining, based on the equivalent inductance, a resonance frequency of the resonant cavity formed by the coplanar waveguide, wherein the resonance frequency is an analytical function with the construction parameter of the coplanar waveguide as a variable; and
adjusting the resonance frequency of the resonant cavity to a target resonance frequency by adjusting a value of the construction parameter of the coplanar waveguide.

2. The method of claim 1, wherein the determining, based on the construction parameter, the equivalent inductance of the coplanar waveguide comprises:
determining, based on the construction parameter, equivalent inductance terms of the coplanar waveguide for position points in a width direction of the metal surface, wherein the equivalent inductance term is an analytical term with the construction parameter as the variable; and
superposing the equivalent inductance terms of the coplanar waveguide for the position points in the width direction to obtain the equivalent inductance of the coplanar waveguide.

3. The method of claim 2, wherein the determining, based on the construction parameter, the equivalent inductance terms for the position points on the coplanar waveguide comprises:
determining, based on the construction parameter, geometric inductance terms for the position points on the coplanar waveguide;
determining kinetic inductance terms for the position points on the coplanar waveguide; and
superposing the geometric inductance terms and the kinetic inductance terms to obtain the equivalent inductance terms.

4. The method of claim 2, wherein the superposing the equivalent inductance terms of the coplanar waveguide for the position points in the width direction to obtain the equivalent inductance of the coplanar waveguide comprises:
integrating, based on coordinate points, the equivalent inductance terms to obtain the equivalent inductance of the coplanar waveguide, under a condition that the position point is the coordinate point in the width direction of the metal surface of the coplanar waveguide by taking a center line of the coplanar waveguide as an origin.

5. The method of claim 4, wherein the integrating, based on the coordinate points, the equivalent inductance terms to obtain the equivalent inductance of the coplanar waveguide comprises:
dividing from the origin to half of a width of the metal surface into a first integration segment, and dividing from a starting position of a ground plate of the coplanar waveguide to an infinity position into a second integration segment, in a first direction in the width direction;
integrating, based on the coordinate points in the first integration segment, the equivalent inductance terms to obtain a first integration result, and integrating, based on the coordinate points in the second integration segment, the equivalent inductance terms to obtain a second integration result; and
superposing the first integration result and the second integration result to obtain a superposition result, and using twice the superposition result as the equivalent inductance of the coplanar waveguide.

6. The method of claim 1, wherein the determining, based on the equivalent inductance, the resonance frequency of the resonant cavity formed by the coplanar waveguide comprises:
determining, based on the construction parameter, an equivalent capacitance of the coplanar waveguide;
determining, based on the equivalent inductance and the equivalent capacitance, a phase velocity of an electromagnetic wave in the resonant cavity formed by the coplanar waveguide; and
determining, based on the phase velocity and a length of the coplanar waveguide in the construction parameter, the resonance frequency of the resonant cavity formed by the coplanar waveguide.

7. The method of claim 1, wherein the adjusting the resonance frequency of the resonant cavity to the target resonance frequency by adjusting the value of the construction parameter of the coplanar waveguide comprises:
adjusting the resonance frequency of the resonant cavity to the target resonance frequency by adjusting the value of a length of the coplanar waveguide in the construction parameter.

8. The method of claim 1, wherein the construction parameter comprises a geometric parameter and a material parameter.

9. The method of claim 8, wherein after the adjusting the resonance frequency of the resonant cavity to the target resonance frequency by adjusting the value of the construction parameter of the coplanar waveguide, the method further comprises:
measuring a target qubit by employing the resonant cavity with the target resonance frequency to obtain a measurement result, wherein the target qubit comprises: a fluxonium qubit.

10. A non-transitory computer-readable storage medium storing a program that is executable by a device to cause the device to perform operations comprising:
acquiring a construction parameter of a coplanar waveguide;
determining, based on the construction parameter, an equivalent inductance of the coplanar waveguide, wherein the equivalent inductance is a superposition of geometric inductance and kinetic inductance, and the equivalent inductance represents current density distribution on a metal surface of the coplanar waveguide;
determining, based on the equivalent inductance, a resonance frequency of a resonant cavity formed by the coplanar waveguide, wherein the resonance frequency is an analytical function with the construction parameter of the coplanar waveguide as a variable; and
adjusting the resonance frequency of the resonant cavity to a target resonance frequency by adjusting a value of the construction parameter of the coplanar waveguide.

11. The non-transitory computer-readable storage medium of claim 10, wherein the operation of determining, based on the construction parameter, the equivalent inductance of the coplanar waveguide comprises:
determining, based on the construction parameter, equivalent inductance terms of the coplanar waveguide for position points in a width direction of the metal surface, wherein the equivalent inductance term is an analytical term with the construction parameter as the variable; and
superposing the equivalent inductance terms of the coplanar waveguide for the position points in the width direction to obtain the equivalent inductance of the coplanar waveguide.

12. The non-transitory computer-readable storage medium of claim 11, wherein the operation of determining, based on the construction parameter, the equivalent inductance terms for the position points on the coplanar waveguide comprises:
determining, based on the construction parameter, geometric inductance terms for the position points on the coplanar waveguide;
determining kinetic inductance terms for the position points on the coplanar waveguide; and
superposing the geometric inductance terms and the kinetic inductance terms to obtain the equivalent inductance terms.

13. The non-transitory computer-readable storage medium of claim 11, wherein the operation of superposing the equivalent inductance terms of the coplanar waveguide for the position points in the width direction to obtain the equivalent inductance of the coplanar waveguide comprises:
integrating, based on coordinate points, the equivalent inductance terms to obtain the equivalent inductance of the coplanar waveguide, under a condition that the position point is the coordinate point in the width direction of the metal surface of the coplanar waveguide by taking a center line of the coplanar waveguide as an origin.

14. The non-transitory computer-readable storage medium of claim 13, wherein the operation of integrating, based on the coordinate points, the equivalent inductance terms to obtain the equivalent inductance of the coplanar waveguide comprises:
dividing from the origin to half of a width of the metal surface into a first integration segment, and dividing from a starting position of a ground plate of the coplanar waveguide to an infinity position into a second integration segment, in a first direction in the width direction;
integrating, based on the coordinate points in the first integration segment, the equivalent inductance terms to obtain a first integration result, and integrating, based on the coordinate points in the second integration segment, the equivalent inductance terms to obtain a second integration result; and
superposing the first integration result and the second integration result to obtain a superposition result, and using twice the superposition result as the equivalent inductance of the coplanar waveguide.

15. The non-transitory computer-readable storage medium of claim 10, wherein the operation of determining, based on the equivalent inductance, the resonance frequency of the resonant cavity formed by the coplanar waveguide comprises:
determining, based on the construction parameter, an equivalent capacitance of the coplanar waveguide;
determining, based on the equivalent inductance and the equivalent capacitance, a phase velocity of an electromagnetic wave in the resonant cavity formed by the coplanar waveguide; and
determining, based on the phase velocity and a length of the coplanar waveguide in the construction parameter, the resonance frequency of the resonant cavity formed by the coplanar waveguide.

16. The non-transitory computer-readable storage medium of claim 10, wherein the operation of adjusting the resonance frequency of the resonant cavity to the target resonance frequency by adjusting the value of the construction parameter of the coplanar waveguide comprises:
adjusting the resonance frequency of the resonant cavity to the target resonance frequency by adjusting the value of a length of the coplanar waveguide in the construction parameter.

17. The non-transitory computer-readable storage medium of claim 10, wherein the construction parameter comprises a geometric parameter and a material parameter.

18. The non-transitory computer-readable storage medium of claim 17, wherein after the operation of adjusting the resonance frequency of the resonant cavity to the target resonance frequency by adjusting the value of the construction parameter of the coplanar waveguide, the operations further comprise:
measuring a target qubit by employing the resonant cavity with the target resonance frequency to obtain a measurement result, wherein the target qubit comprises: a fluxonium qubit.

19. A computer device, comprising:
a memory configured to store a computer program; and
one or more processors configured to run the computer program stored in the memory, to cause the computer device to execute operations comprising:
acquiring a construction parameter of a coplanar waveguide;
determining, based on the construction parameter, an equivalent inductance of the coplanar waveguide, wherein the equivalent inductance is a superposition of geometric inductance and kinetic inductance, and the equivalent inductance represents current density distribution on a metal surface of the coplanar waveguide;
determining, based on the equivalent inductance, a resonance frequency of a resonant cavity formed by the coplanar waveguide, wherein the resonance frequency is an analytical function with the construction parameter of the coplanar waveguide as a variable; and
adjusting the resonance frequency of the resonant cavity to a target resonance frequency by adjusting a value of the construction parameter of the coplanar waveguide.

20. The computer device of claim 19, wherein the operation of determining, based on the construction parameter, the equivalent inductance of the coplanar waveguide comprises:
determining, based on the construction parameter, equivalent inductance terms of the coplanar waveguide for position points in a width direction of the metal surface, wherein the equivalent inductance term is an analytical term with the construction parameter as the variable; and
superposing the equivalent inductance terms of the coplanar waveguide for the position points in the width direction to obtain the equivalent inductance of the coplanar waveguide.
